(19) United States
(12) Patent Application Publication
(10) Pub. No.: US 2026/0150595 A1
(43) Pub. Date: May 28, 2026

(54) MANUFACTURING METHOD FOR SEMICONDUCTOR DEVICE

(71) Applicant: HPSP Co., Ltd., Hwaseong-si, Gyeonggi-do (KR)

(72) Inventor: Sung-Kil CHO, Hwaseong-si, Gyeonggi-do (KR)

(21) Appl. No.: 19/114,536

(22) PCT Filed: Sep. 21, 2023
(86) PCT No.: PCT/KR2023/014446

§ 371 Date: Mar. 24, 2025

(30) Foreign Application Priority Data
Sep. 23, 2022 (KR) 10-2022-0120982

(51) Int. Cl. H10P 14/60; C23C 8/24; H10D 64/01

(52) U.S. Cl. CPC H10P 14/6316; C23C 8/24; H10D 64/037

(57) ABSTRACT

The present invention relates to a manufacturing method for a semiconductor device. The manufacturing method for a semiconductor device, according to one embodiment, may comprise the steps of: forming an insulation layer; forming a barrier layer on the insulation layer; performing nitrification on the barrier layer; and forming a metal electrode on the barrier layer. In one embodiment, the step of performing nitrification can comprise a step of performing a high pressure nitridation (HPN). According to embodiments, the quality of a barrier layer is improved during the manufacture of a semiconductor device such that electrical properties of the barrier layer and a metal electrode are improved, and thus electrical properties of the semiconductor device can also be enhanced.

### FIELD

The present disclosure relates to a method for manufacturing a semiconductor device.

### DESCRIPTION OF RELATED ART

A semiconductor device is a component mainly used in an electronic circuit or a similar device that uses the electrical conduction characteristics of a semiconductor. The semiconductor device may be classified into a memory semiconductor device and a non-memory semiconductor device. The memory semiconductor device may be classified into a volatile memory device such as DRAM and SRAM and a non-volatile memory device such as Mask ROM, EP ROM, EEP ROM, and flash memory.

FIG. 1 illustrates a structure of a general semiconductor device.

Referring to FIG. 1, the semiconductor device may include an insulating layer 12 formed on a substrate 11 having a predetermined structure and a metal electrode 14 formed on the insulating layer 12.

The metal electrode 14 may include, for example, a metal material such as Al, Cu, W, Mo, or Ru. Metal ions, oxygen, moisture, etc. included in the metal electrode 14 may be diffused into the insulating layer 12 to contaminate the insulating layer 12 or cause a problem such as a spike. In order to prevent such a problem, a barrier layer 13 serving as a barrier may be formed between the insulating layer 12 and the metal electrode 14 during the manufacturing process of the semiconductor device. The barrier layer 13 may include a metal material (e.g., Ti, Ta, TiN, TaN, TiOx, TaOx, W, WN, WO, etc.).

However, when the metal electrode 14 has been formed on the barrier layer 13 after the barrier layer 13 has been formed, conformality of the barrier layer 13 is lowered, and foreign substances (e.g., H₂ or D₂) are present inside the barrier layer 13. The deterioration of the electrical characteristics due to the low quality of the barrier layer 13 may also deteriorate the electrical characteristics of the metal electrode 14. Thus, there is a problem in that electrical characteristics of the semiconductor device are lowered.

### DISCLOSURE

### Technical Purpose

A purpose of the present disclosure is to provide a method for manufacturing a semiconductor device capable of improving electrical characteristics of a barrier layer and a metal electrode by improving a quality of the barrier layer in a process of manufacturing the semiconductor device.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

### Technical Solution

In an embodiment, a method for manufacturing a semiconductor device may include forming an insulating layer, forming a barrier layer on the insulating layer, performing a nitridation process on the barrier layer, and forming a metal electrode on the barrier layer.

In an embodiment, the performing of the nitridation process may include performing a high pressure nitridation (HPN) process.

In an embodiment, the HPN process may be performed in a chamber into which a reactive gas including nitrogen is injected under an inert gas atmosphere.

In an embodiment, a concentration of the reactive gas in the chamber may be 5% or higher, when the HPN process is performed.

In an embodiment, the internal air pressure of the chamber may be maintained at 2 to 50 atm, when the HPN process is performed.

In an embodiment, the internal temperature of the chamber may be maintained at 200 to 1000° C., when the HPN process is performed.

The method may further include performing a high pressure anneal (HPA) process on the barrier layer.

In an embodiment, the HPA process may be performed in a chamber in which a reactive gas including hydrogen is injected under an inert gas atmosphere.

In an embodiment, a concentration of the reactive gas in the chamber may be 5% or higher, when the HPN process is performed.

In an embodiment, the internal air pressure of the chamber may be maintained at 2 to 50 atm, when the HPN process is performed.

In an embodiment, the internal temperature of the chamber may be maintained at 200 to 1000° C., when the HPN process is performed.

### Technical Effect

According to embodiments, the electrical characteristics of the barrier layer and the metal electrode may be improved by improving the quality of the barrier layer in the process of manufacturing the semiconductor device, and thus the electrical characteristics of the semiconductor device may also be improved.

### BRIEF DESCRIPTION OF DRAWINGS

FIG. 1 illustrates a structure of a general semiconductor device.

FIGS. 2 and 3 illustrate a process of manufacturing a semiconductor device according to an embodiment.

FIGS. 4 to 8 illustrate a process of manufacturing a semiconductor device according to another embodiment.

FIG. 9 is a graph showing a resistance value of a barrier layer measured when a voltage is applied to each of a general semiconductor device and a semiconductor device according to an embodiment.

FIG. 10 is a graph showing a resistance value of a metal electrode measured when a voltage is applied to each of a general semiconductor device and a semiconductor device according to an embodiment.

### DETAILED DESCRIPTIONS

The above-described purposes, features, and advantages will be described in detail with reference to the accompanying drawings, and accordingly, a person having ordinary skill in the art to which the present disclosure belongs will be able to easily implement the embodiments of the present disclosure. In describing the present disclosure, when it is determined that a detailed description of known technologies related to the present disclosure may unnecessarily obscure a gist of the present disclosure, the detailed description thereof will be omitted. Hereinafter, preferred embodiments of the present disclosure will be described in detail with reference to the accompanying drawings. In the drawings, the same reference numerals refer to the same or similar elements.

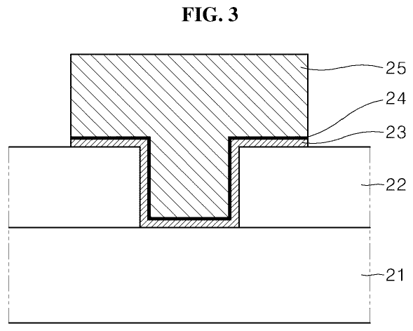

FIGS. 2 and 3 illustrate a process of manufacturing a semiconductor device according to an embodiment.

As illustrated in FIGS. 2 and 3, according to a method for manufacturing a semiconductor device according to an embodiment, an insulating layer 22 is formed on a substrate 21, and a barrier layer 23 is formed on the insulating layer 22.

In an embodiment, the substrate 21 may be a silicon substrate, a germanium substrate, or a silicon-germanium substrate.

In an embodiment, the insulating layer 22 may be a silicon oxide film formed through a thermal oxidation process or a silicon oxide film formed using a deposition technique.

In an embodiment, the barrier layer 23 may include a metal material (e.g., Ti, Ta, TiN, TaN, TiOx, TaOx, W, WN, WO, etc.).

When the barrier layer 23 has been formed, a nitridation process is performed on the barrier layer 23 (refer to 24). Performing the nitridation process on the barrier layer 23 may allow a content of the nitrogen (N) component in the barrier layer 23 to increase, and allow impurities in the barrier layer 23 to be removed. In addition, as the nitridation process is performed on the barrier layer 23, conformality of the barrier layer 23 may be increased.

In an embodiment, the nitridation process performed on the barrier layer 23 may include a High Pressure Nitridation (HPN) process.

In an embodiment, the HPN process may be performed in a chamber into which a reactive gas including nitrogen is injected under an inert gas atmosphere.

Examples of the inert gas include N₂, Ar, and He. However, the type of the inert gas is not limited thereto.

Examples of the reactive gas including nitrogen include NH₂ and NH₃. However, the type of the reactive gas including nitrogen is not limited thereto.

In an embodiment, when the HPN process is performed, the concentration of the reactive gas including nitrogen in the chamber may be 5% or greater. For example, when the HPN process is performed, the concentration of the reactive gas including nitrogen in the chamber may be in a range of 5% to 100%.

In one embodiment, an internal air pressure of the chamber may be maintained in a range between 2 and 50 atm when the HPN process is performed.

In one embodiment, the internal temperature of the chamber may be maintained in a range between 200 and 1000° C. when the HPN process is performed.

When the nitridation process is performed on the barrier layer 23 as described above, the conformality of the barrier layer 23 increases, and thus electrical characteristics of the barrier layer 23 may be improved. In addition, when the barrier layer 23 has a high conformality, the conformality of the metal electrode 25 formed on the barrier layer 23 is also increased, and thus electrical characteristics of the metal electrode 25 may be improved.

After the nitridation process 24 has been performed on the barrier layer 23, a metal electrode 25 may be formed on the nitridated barrier layer 23.

The metal electrode 25 may be formed by plasma sputtering or a physical vapor deposition (PVD) process like an evaporation manner. However, a method of forming the metal electrode 25 is not limited thereto. For example, the metal electrode 25 may include a metal material such as W, Al, Ti, Ta, Co, Mo, Ru, or Cu.

In another embodiment, a High Pressure Anneal (HPA) process may be performed on the barrier layer 23.

In an embodiment, the HPA process may be performed in a chamber in which a reactive gas including hydrogen is injected under an inert gas atmosphere.

Examples of the inert gas include N2, Ar, and He. However, the type of the inert gas is not limited thereto.

Examples of the reactive gas including hydrogen include H₂ and D₂. However, the type of the reactive gas including hydrogen is not limited thereto.

In an embodiment, when the HPA process is performed, the concentration of the reactive gas including hydrogen in the chamber may be 5% or higher. For example, when the HPN process is performed, the concentration of the reactive gas including hydrogen in the chamber may be in a range of 5% to 100%.

In one embodiment, the internal air pressure of the chamber may be maintained in a range between 2 and 50 atm when the HPA process is performed.

In one embodiment, the internal temperature of the chamber may be maintained in a range between 200 and 1000° C. when the HPA process is performed.

In an embodiment, after the HPA process has been performed on the barrier layer 23, the HPN process may be performed on the barrier layer 23. In another embodiment, after the HPN process has been performed on the barrier layer 23, the HPA process may be performed on the barrier layer 23.

When the HPA process and the HPN process are performed together on the barrier layer 23, the conformality of the barrier layer 23 and the conformality of the metal electrode 25 are further improved compared to when only the HPN process is performed on the barrier layer 23. Accordingly, electrical characteristics of the barrier layer 23 and electrical characteristics of the metal electrode 25 may be further improved.

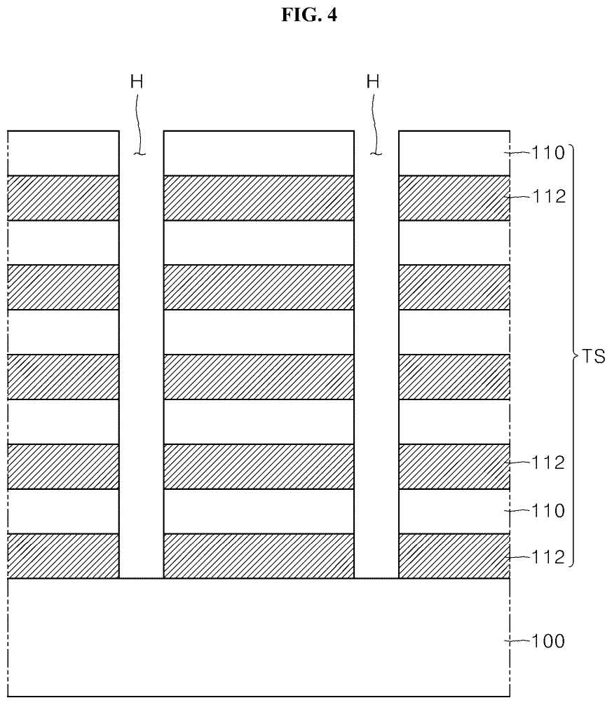

FIGS. 4 to 8 illustrate a process of manufacturing a semiconductor device according to another embodiment.

Referring to FIG. 4, sacrificial layers 112 and insulating layers 110 may be alternately and repeatedly deposited on a substrate 100 to form a thin-film structure TS.

In an embodiment, the substrate 100 may be a silicon substrate, a germanium substrate, or a silicon-germanium substrate.

In an embodiment, the sacrificial layers 112 may be formed to have the same thickness. However, according to another embodiment, the lowermost and uppermost sacrificial layers 112 among the sacrificial layers 112 may be formed to be thicker than the sacrificial layers 112 located therebetween.

In an embodiment, the insulating layers 110 may have the same thickness. In another embodiment, some of the insulating layers 110 may have different thicknesses.

In an embodiment, the sacrificial layers 112 and the insulating layers 110 may be formed using a thermal CVD process, a plasma enhanced CVD process, a physical CVD process, or an Atomic Layer Deposition (ALD) process.

In an embodiment, the sacrificial layers 112 and the insulating layers 110 may include different materials having different etch selectivity from each other. For example, the sacrificial layer 112 may be at least one of a silicon film, a silicon oxide film, a silicon carbide film, a silicon oxynitride film, and a silicon nitride film. The insulating layer 110 may be at least one of a silicon film, a silicon oxide film, a silicon carbide film, a silicon oxynitride film, and a silicon nitride film, and may be made of a material different from that of the sacrificial layers 112. For example, the sacrificial layer 112 may be made of a silicon nitride film, and the insulating layer 110 may be made of a silicon oxide film. However, according to another embodiment, the sacrificial layers 112 may be made of a conductive material, and the insulating layers 110 may be made of an insulating material

Through-holes H may be formed to extend through the thin-film structure TS to expose the substrate 100. In a plan view on top of an upper surface of the thin-film structure TS, the through-holes H may be two-dimensionally formed. According to an embodiment, the through-holes H may be arranged along the first direction D1. However, according to another embodiment, the through-holes H may be arranged in a zigzag manner along the first direction D1.

The formation of the through-holes H may include forming a first mask pattern (not shown) having openings defined therein defining areas in which the through-holes H are to be formed on the thin-film structure TS, and anisotropically etching the thin-film structure TS using the first mask pattern as an etch mask. The first mask pattern may be made of a material having selectivity with respect to the sacrificial layers 112 and the insulating layers 110. The upper surface of the substrate 100 may be over-etched by the etching process, and thus, a top portion of the substrate 100 may be recessed.

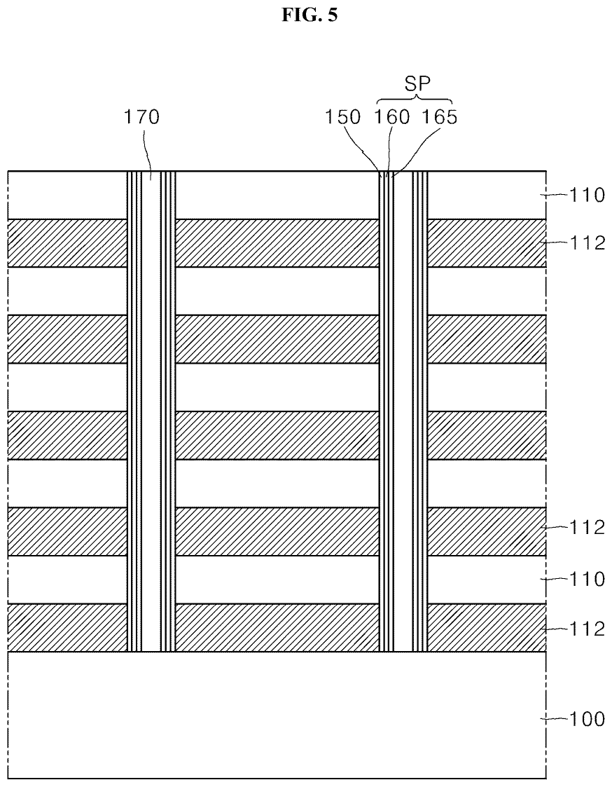

Next, as illustrated in FIG. 5, a charge storage structure 150 and a first semiconductor pattern 160 may be formed to cover an inner wall of each of the through-holes H and to expose the substrate 100.

In detail, a charge storage structure film (not shown) and a first semiconductor film (not shown) may be sequentially formed to cover an inner wall of each of the through-holes H. The charge storage structure film and the first semiconductor film may be formed to fill a portion of each of the through-holes H. Each of the through-holes H may not be entirely filled with the charge storage structure film and the first semiconductor film.

The charge storage structure film may cover a portion of the upper surface of the substrate 100 exposed through each of the through-holes H. The charge storage structure film may be deposited using, for example, plasma enhanced chemical vapor deposition (CVD), physical chemical vapor deposition (CVD), or Atomic Layer Deposition (ALD).

The first semiconductor film may be formed on the charge storage structure film. According to an embodiment, the first semiconductor film may be a semiconductor material film formed using one of atomic layer deposition (ALD) and chemical vapor deposition (CVD) techniques. The first semiconductor film may be, for example, a polycrystalline silicon film. According to an embodiment, the first semiconductor film may be amorphous during deposition, or may be crystallized using an annealing process etc.

After the charge storage structure film and the first semiconductor film have been sequentially formed, the substrate 100 may be exposed by anisotropically etching the charge storage structure film and the first semiconductor film. Accordingly, the first semiconductor pattern 160 and the charge storage structure 150 may be formed on the inner wall of each of the through-holes H. That is, the charge storage structure 150 and the first semiconductor pattern 160 may be formed in a cylindrical shape having both open opposing ends. As a result of over-etching during the anisotropic etching of the first semiconductor film and the charge storage structure film, a portion of the upper surface of the substrate 100 not covered with the first semiconductor pattern 160 and the charge storage structure 150 may be recessed.

In an embodiment, the charge storage structure 150 may include a tunnel insulating layer, a charge storage layer, and a blocking insulating layer which are sequentially stacked between the first semiconductor pattern 160 and the thin-film structure TS. The blocking insulating layer, the charge storage layer, and the tunnel insulating layer may be sequentially deposited on the inner wall of each of the through-holes H using plasma enhanced chemical vapor deposition (CVD), physical chemical vapor deposition (CVD), or Atomic Layer Deposition (ALD).

Next, a second semiconductor pattern 165 and a buried insulating pattern 170 may be formed to fill a remaining portion of each of the through-holes H.

Specifically, a second semiconductor film (not shown) and a buried insulating film (not shown) may be sequentially formed on the substrate 100 on which the charge storage structure 150 and the first semiconductor pattern 160 have been formed.

The second semiconductor film may be formed to have a thickness such that the second semiconductor film does not entirely fill each of the through-holes H. The second semiconductor film may cover an inner wall of each of the through-holes H, and may cover a portion of the upper surface of the substrate 100 not covered with the charge storage structure 150 and the first semiconductor pattern 160. The second semiconductor film may connect the substrate 100 and the first semiconductor pattern 160 to each other.

The second semiconductor film may be a semiconductor material film formed using one of atomic layer deposition (ALD) and chemical vapor deposition (CVD) techniques. The second semiconductor film may be, for example, a polycrystalline silicon film. According to an embodiment, the second semiconductor film may be amorphous during deposition, or may be crystallized using an annealing process etc. The buried insulating film may be formed to entirely fill the inside of each of the through-holes H. The buried insulating film may be at least one of an insulating material film and a silicon oxide film formed using SOG technology.

The second semiconductor pattern 165 and the buried insulating pattern 170 may be formed in each of the through-holes H by planarizing the buried insulating film and the second semiconductor film. The second semiconductor pattern 165 and the buried insulating pattern 170 may be locally formed in each of the through-holes H by the planarization process. The first and second semiconductor patterns 160 and 165 may be defined as a semiconductor pattern SP.

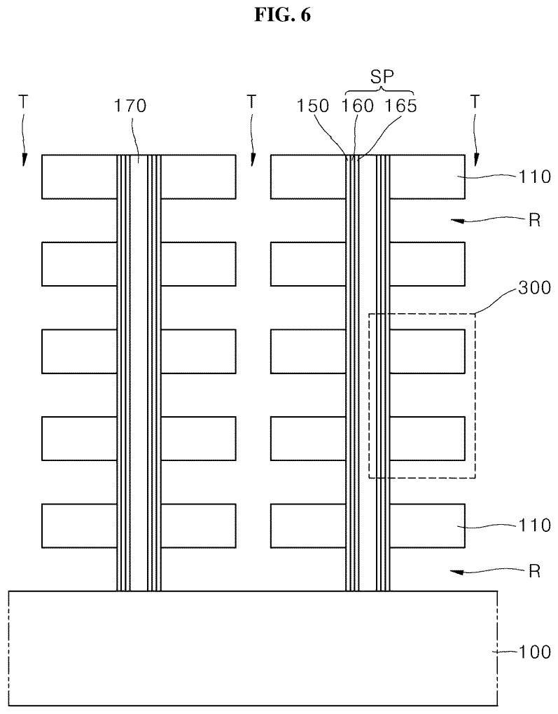

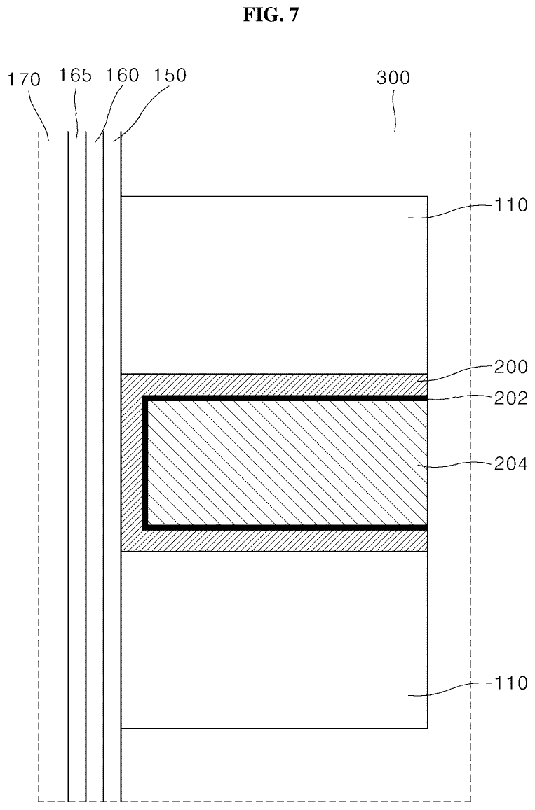

Next, as illustrated in FIG. 6, the thin-film structure TS may be patterned to form a trench T exposing a portion of the substrate 100 between the through-holes H adjacent to each other.

The formation of the trench T may include forming a second mask pattern (not shown) defining a planar position at which the trench T is to be formed, on the thin-film structure TS, and anisotropically etching the thin-film structure TS using the second mask pattern as an etch mask.

The trench T may be formed to be spaced apart from the semiconductor pattern SP so as to expose sidewalls of the sacrificial layers 112 and the insulating layers 110. In a plan view, the trench T may be formed in a line shape or a rectangular shape, and in a vertical depth, the trench T may be formed to expose the upper surface of the substrate 100. During the etching process, the upper portion of the substrate 100 may be over-etched, and thus, the upper portion of the substrate 100 may be recessed.

Unlike the illustrated example, the trench T may have a width varying depending on a distance thereof from the substrate 100 due to an anisotropic etching process. That is, the width of a lower end of the trench T may be smaller than the width of an upper end of the trench T.

Next, recess areas R may be formed between the insulating layers 110 by removing the sacrificial layers 112 exposed through the trench T. The recess areas R may be formed by isotropically etching the sacrificial layers 112 using an etching condition having an etch selectivity with respect to the insulating layers 110, the charge storage structure 150, the semiconductor pattern SP, the lower insulating layer 105, and the substrate 100. The sacrificial layers 112 may be entirely removed by an isotropic etching process. In one example, when the sacrificial layers 112 are silicon nitride films and the insulating layers 110 are silicon oxide films, the etching process may be performed using an etchant including phosphoric acid.

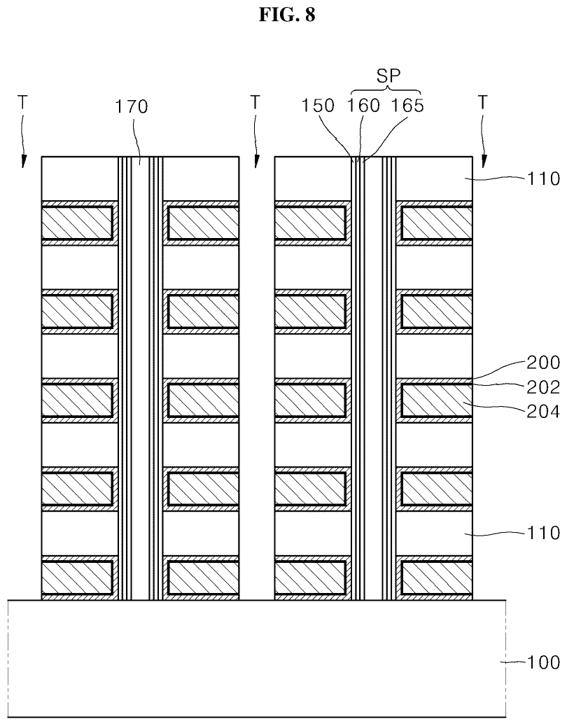

Next, as shown in an enlarged view 300 of FIG. 7, a barrier layer 200 is formed inside each of the recess areas R. The barrier layer 200 may be formed on the insulating layers 110 and the charge storage structure 150.

In an embodiment, the barrier layer 200 may include a metal material (e.g., Ti, Ta, TiN, TaN, TiOx, TaOx, W, WN, WO, etc.).

Once the barrier layer 200 has been formed, a nitridation process is performed on the barrier layer 200 (refer to 202). Performing the nitridation process on the barrier layer 200 may allow the content of the nitrogen (N) component in the barrier layer 200 to increase, and allow impurities in the barrier layer 200 to be removed. In addition, as the nitridation process is performed on the barrier layer 200, the conformality of the barrier layer 200 may be increased.

In an embodiment, the nitridation process performed on the barrier layer 200 may include a HPN process.

In an embodiment, the HPN process may be performed in a chamber in which a reactive gas including nitrogen is injected under an inert gas atmosphere.

Examples of the inert gas include N₂, Ar, and He. However, the type of the inert gas is not limited thereto.

Examples of the reactive gas including nitrogen include NH₂ and NH₃. However, the type of the reactive gas including nitrogen is not limited thereto.

In an embodiment, when the HPN process is performed, the concentration of the reactive gas including nitrogen in the chamber may be 5% or higher. For example, when the HPN process is performed, the concentration of the reactive gas including nitrogen in the chamber may be in a range of 5% to 100%.

In one embodiment, the internal air pressure of the chamber may be maintained in a range between 2 and 50 atm when the HPN process is performed.

In one embodiment, the internal temperature of the chamber may be maintained in a range between 200 and 1000° C. when the HPN process is performed.

When the nitridation process has been performed on the barrier layer 200 as described above, the conformality of the barrier layer 200 increases, and thus the electrical characteristics of the barrier layer 200 may be improved. In addition, when the barrier layer 200 has a high conformality, the conformality of a metal electrode 204 formed on the barrier layer 200 is also increased, and thus electrical characteristics of the metal electrode 204 may be improved.

After the nitridation process 202 has been performed on the barrier layer 200, the metal electrode 204 may be formed on the nitridated barrier layer 200.

The metal electrode 204 may be formed by plasma sputtering or a PVD process in an evaporation manner. However, a method of forming the metal electrode 204 is not limited thereto. For example, the metal electrode 204 may include a metal material such as W, Al, Ti, Ta, Co, Mo, Ru, or Cu.

According to another embodiment, an HPA process may be performed on the barrier layer 200.

In an embodiment, the HPA process may be performed in a chamber in which a reactive gas including hydrogen is injected under an inert gas atmosphere.

Examples of the inert gas include N₂, Ar, and He. However, the type of the inert gas is not limited thereto.

Examples of the reactive gas including hydrogen include H₂ and D₂. However, the type of the reactive gas including hydrogen is not limited thereto.

In an embodiment, when the HPA process is performed, the concentration of the reactive gas including hydrogen in the chamber may be 5% or higher. For example, when the HPA process is performed, the concentration of the reactive gas including hydrogen in the chamber may be in a range of 5% to 100%.

In one embodiment, the internal air pressure of the chamber may be maintained in a range between 2 and 50 atm when the HPA process is performed.

In one embodiment, the internal temperature of the chamber may be maintained in a range between 200 and 1000° C. when the HPA process is performed.

In an embodiment, after the HPA process has been performed on the barrier layer 200, the HPN process may be performed on the barrier layer 200. In another embodiment, after the HPN process has been performed on the barrier layer 200, the HPA process may be performed on the barrier layer 200.

When the HPA process and the HPN process are performed together on the barrier layer 200, the conformality of the barrier layer 200 and the conformality of the metal electrode 204 are further improved compared to when only the HPN process is performed on the barrier layer 200. Accordingly, electrical characteristics of the barrier layer 200 and electrical characteristics of the metal electrode 204 may be further improved.

Through this process, the semiconductor device as shown in FIG. 8 may be completed.

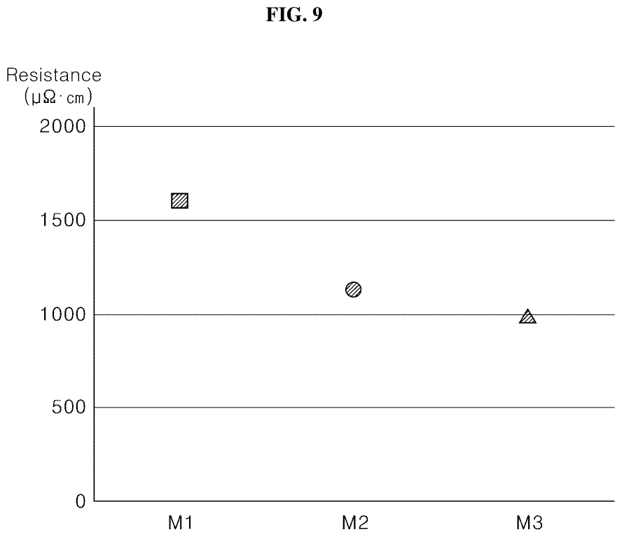

FIG. 9 is a graph showing a resistance value of a barrier layer measured when a voltage is applied to each of a general semiconductor device and a semiconductor device according to an embodiment.

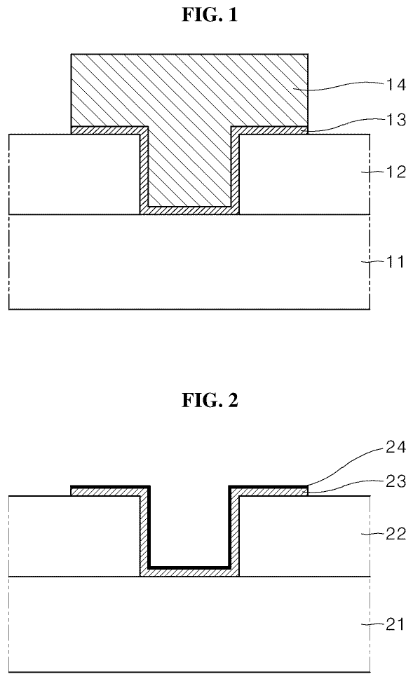

In FIG. 9, M1 is related to a general semiconductor device illustrated in FIG. 1, that is, a semiconductor device in which a HPN process or a HPA process is not performed on the barrier layer 13. In addition, in FIG. 9, M2 is related to a semiconductor device having a structure as shown in FIG. 3 and in which a HPN process is performed on the barrier layer 23. In addition, in FIG. 9, M3 is related to a semiconductor device having the structure as shown in FIG. 3 and in which both a HPA process and a HPN process are performed on the barrier layer 23.

As illustrated in FIG. 9, a resistance value of the barrier layer 13 when a voltage is applied to the semiconductor device M1 is greater than a resistance value of the barrier layer 23 when a voltage is applied to the semiconductor device M2. According to this result, it may be identified that when the HPN process is applied to the barrier layer, the conformality of the barrier layer is improved, and thus the resistance of the barrier layer is reduced.

In addition, as illustrated in FIG. 9, a resistance value of the barrier layer 23 when a voltage is applied to the semiconductor element M2 is greater than a resistance value of the barrier layer 23 when a voltage is applied to the semiconductor element M3. According to this result, it may be identified that when the HPA process and the HPN process are applied together to the barrier layer, the conformality of the barrier layer is improved compared to when only the HPN process is applied to the barrier layer, and thus the resistance of the barrier layer is further reduced.

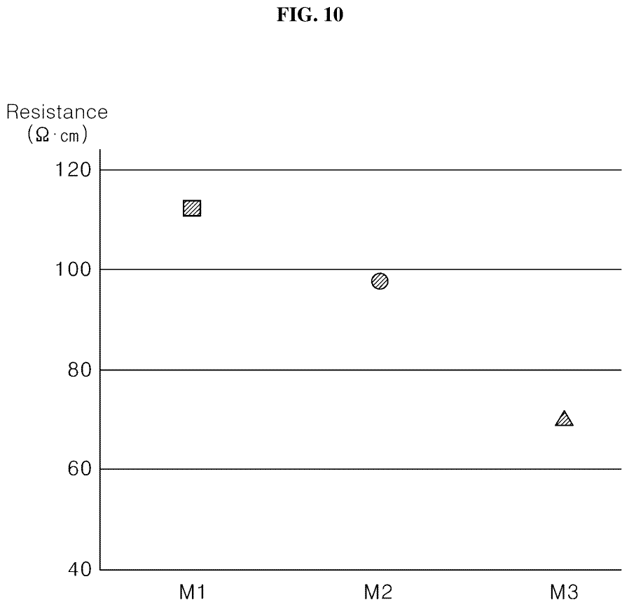

FIG. 10 is a graph showing a resistance value of a metal electrode measured when is applied to each of a general semiconductor device and a semiconductor device according to an embodiment.

In FIG. 10, M1 refers to a general semiconductor device illustrated in FIG. 1, that is, a semiconductor device in which a HPN process or a HPA process on the barrier layer 13 is not performed. In addition, in FIG. 10, M2 refers to a semiconductor device having a structure as shown in FIG. 3 and in which a HPN process is performed on the barrier layer 23. In addition, in FIG. 10, M3 refers to a semiconductor device having the structure as shown in FIG. 3 and in which both a HPA process and a HPN process are performed on the barrier layer 23.

As illustrated in FIG. 10, a resistance value of the metal electrode 14 when a voltage is applied to the semiconductor device M1 is greater than a resistance value of the metal electrode 25 when a voltage is applied to the semiconductor device M2. According to this result, it may be identified that when the HPN process is applied to the barrier layer, the conformality of the metal electrode is improved, and thus the resistance of the metal electrode is reduced.

In addition, as illustrated in FIG. 10, a resistance value of the metal electrode 25 when a voltage is applied to the semiconductor device M2 is greater than a resistance value of the metal electrode 25 when a voltage is applied to the semiconductor device M3. According to this result, it may be identified that when the HPA process and the HPN process are applied together to the barrier layer, the conformality of the metal electrode is improved compared to when only the HPN process is applied to the barrier layer, and thus the resistance of the metal electrode is further reduced.

Although the present disclosure has been described above with reference to the accompanying drawings, the present disclosure is not limited by the embodiments disclosed herein and the drawings, and it is obvious that various modifications may be made by those skilled in the art within the scope of the technical idea of the present disclosure. In addition, although the effects based on the configuration of the present disclosure are not explicitly described above in the description of the embodiment of the present disclosure, it is obvious that predictable effects from the configuration should also be recognized.

1. A method for manufacturing a semiconductor device, the method comprising:
forming an insulating layer;
forming a barrier layer on the insulating layer;
performing a nitridation process on the barrier layer; and
forming a metal electrode on the barrier layer,
wherein the performing of the nitridation process includes performing a high pressure nitridation (HPN) process.

2. The method for manufacturing the semiconductor device of claim 1, wherein the HPN process is performed in a chamber in which a reactive gas including nitrogen is injected under an inert gas atmosphere.

3. The method for manufacturing the semiconductor device of claim 2, wherein a concentration of the reactive gas in the chamber is 5% or higher, when the HPN process is performed.

4. The method for manufacturing the semiconductor device of claim 1, wherein an internal pressure of the chamber is maintained in a range of 2 to 50 atm, when the HPN process is performed.

5. The method for manufacturing the semiconductor device of claim 1, an internal temperature of the chamber is maintained in a range of 200 to 1000° C., when the HPN process is performed.

6. The method for manufacturing the semiconductor device of claim 1, wherein the method further comprises performing a high pressure anneal (HPA) process on the barrier layer

7. The method for manufacturing the semiconductor device of claim 6, wherein the HPA process is performed in a chamber in which a reactive gas including hydrogen is injected under an inert gas atmosphere.

8. The method for manufacturing the semiconductor device of claim 7, the concentration of the reactive gas in the chamber is 5% or higher, when the HPN process is performed.

9. The method for manufacturing the semiconductor device of claim 6, wherein an internal pressure of the chamber is maintained in a range of 2 to 50 atm, when the HPN process is performed.

10. The method for manufacturing the semiconductor device of claim 6, wherein an internal temperature of the chamber is maintained in a range of 200 to 1000° C., when the HPN process is performed.
